(19) United States
(12) Patent Application Publication
(10) Pub. No.: US 2013/0048048 A1
(43) Pub. Date: Feb. 28, 2013

(54) SYSTEM AND METHODS FOR CONTROLLING SOLAR MODULE TRACKERS

(71) Applicants: Kent Flanery, Worthington, KY (US); Kevin Collins, Park Ridge, NJ (US)

(72) Inventors: Kent Flanery, Worthington, KY (US); Kevin Collins, Park Ridge, NJ (US)

(21) Appl. No.: 13/214,674

(22) Filed: Aug. 22, 2011

(51) Int. Cl. H01L 31/052

(52) U.S. Cl. 136/246

(57) ABSTRACT

A method and apparatus for controlling the inclination angle of a solar module. The apparatus includes a solar module mounted on a rotatable support that is rotated by a mechanism. The apparatus further includes a sensor and a controller for controlling the mechanism to adjust the inclination angle of the solar module based on the sensed conditions.

### FIELD OF THE INVENTION

Embodiments of the invention relate to the field of photovoltaic power generation systems, and more particularly to methods and systems used to control solar module trackers.

### BACKGROUND OF THE INVENTION

Photovoltaic power generation systems convert solar radiation to electrical current using photovoltaic modules. Since direct irradiance (and therefore electrical current output) varies according to the cosine of the angle of deviation from a position normal to the plane of the photovoltaic modules (the “angle of incidence”) at which the sun's rays strike the photovoltaic modules, in systems where the photovoltaic modules remain in a fixed position, electrical current output rises and falls as the sun travels from the eastern to western horizon and as the angle of incidence deviates from zero. To provide increased (and more consistent) power generation over the course of a day, power generation systems can employ a tracker mechanism, for example, an electromechanical solar tracker, that changes the inclination angle of photovoltaic modules to maintain an angle of incidence of zero degrees between the sun and the photovoltaic modules.

Solar trackers typically employ an algorithm that uses the current date and time and the latitude and longitude of the system as inputs to approximate the position of the sun. With the position of the sun approximated, the photovoltaic modules can be positioned at substantially zero degrees (the optimum angle of incidence) to the sun. The inclination angle of the photovoltaic modules may then be adjusted at regular intervals throughout the day so that the angle of incidence remains constant. Simple trackers such as these, however, generally operate without external inputs and thus fail to account for other variables that may affect power generation, such as ambient air temperature or module temperature. The trackers also fail to account for other factors or desired operating characteristics, such as desired plant output. Accordingly, more refined methods of controlling photovoltaic plant output are needed that can emphasize desired operating characteristics, and account for variables besides the approximated position of the sun.

### BRIEF DESCRIPTION OF THE DRAWINGS

FIGS. 1A-1B are side and front views of a photovoltaic module and electromechanical tracker, according to an exemplary embodiment.

FIG. 2 is a side view of the FIG. 1A photovoltaic module showing different operating states.

FIG. 3 is side view of a system of photovoltaic modules and electromechanical trackers, according to an exemplary embodiment.

FIG. 4A is side view of a photovoltaic module and electromechanical tracker, according to an exemplary embodiment.

FIG. 4B is an algorithm used to adjust the inclination angle of a photovoltaic module according to an exemplary embodiment.

FIG. 5A is side view of a photovoltaic module and electromechanical tracker, according to an exemplary embodiment.

FIG. 5B is an algorithm used to adjust the inclination angle of a photovoltaic module according to an exemplary embodiment.

FIG. 6A is side view of a photovoltaic module and electromechanical tracker, according to an exemplary embodiment.

FIG. 6B is an algorithm used to adjust the inclination angle of a photovoltaic module according to an exemplary embodiment.

FIG. 7A is side view of a system of photovoltaic module and electromechanical trackers, according to an exemplary embodiment.

FIG. 7B is an algorithm used to adjust the inclination angle of photovoltaic modules according to an exemplary embodiment.

FIG. 8A is side view of a system of photovoltaic modules and electromechanical trackers, according to an exemplary embodiment.

FIG. 8B is an algorithm used to adjust the inclination angle of a photovoltaic module according to an exemplary embodiment.

### DETAILED DESCRIPTION OF THE INVENTION

In the following detailed description, reference is made to the accompanying drawings which form a part hereof, and in which is shown by way of illustration specific embodiments that provide a system and method used to control solar module trackers. These embodiments are described in sufficient detail to enable those skilled in the art to make and use them, and it is to be understood that structural, logical, or procedural changes may be made to the specific embodiments disclosed without departing from the spirit and scope of the invention.

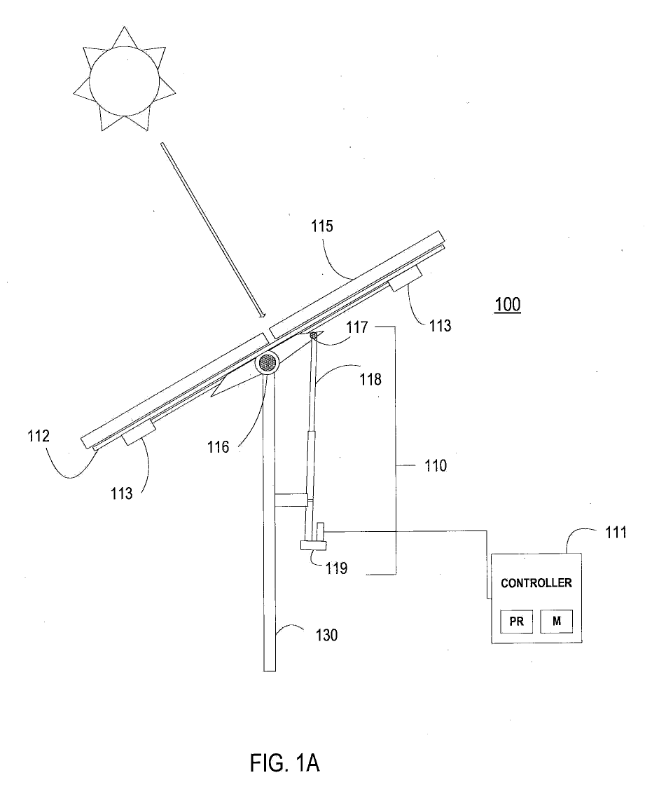

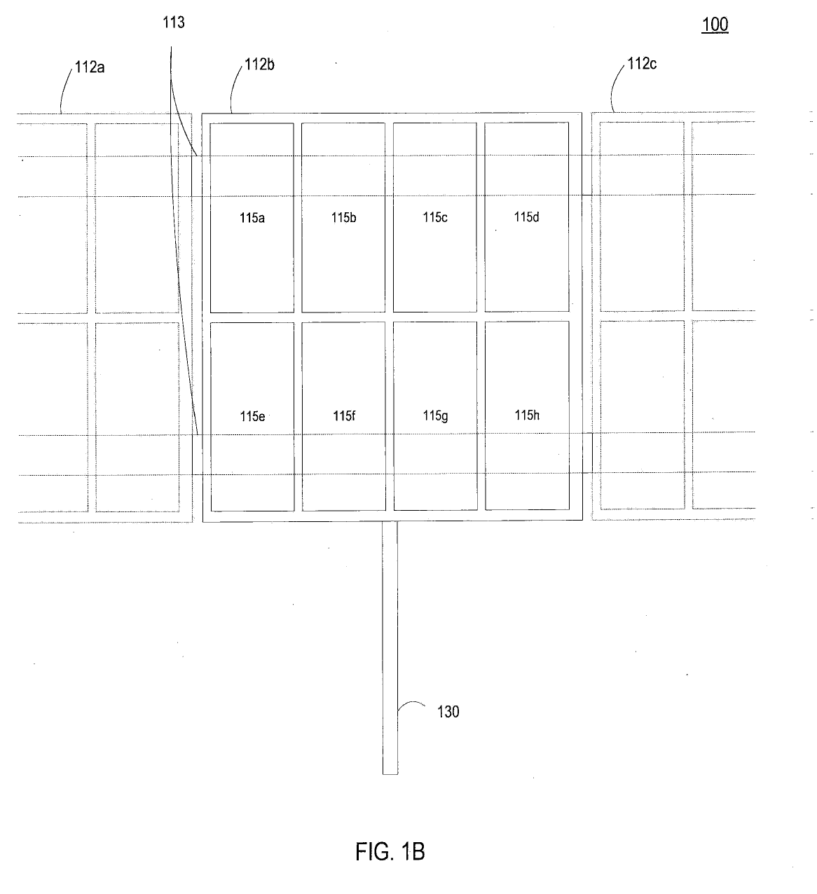

FIG. 1A illustrates a side view of a solar tracking system 100 used to control the inclination angle of a solar module 115 according to an exemplary embodiment. As can be seen in FIG. 1A, one or more solar modules 115 are mounted to a module support 112. The solar tracking system 100 includes, a tracker mechanism, shown in FIG. 1A as an electromechanical tracker 110 that is used to control the inclination angle of module support 112. Module support 112 is mounted on a rotatable bearing and housing 116, which is supported by post 130, thus permitting solar modules 115 to be positioned at a desired angle of incidence (here, zero degrees) to the sun as the sun traverses the sky.

As illustrated in FIG. 1B, the post 130 can accommodate multiple module supports 112a-c, each carrying multiple solar modules 115a-h. Module supports 112a-c can be joined together along rails 113. Three module supports 112a-c are illustrated in FIG. 1B; this is merely exemplary. Eight solar modules 115a-h are illustrated on each module support 112a-c in FIG. 1B; this is also merely exemplary.

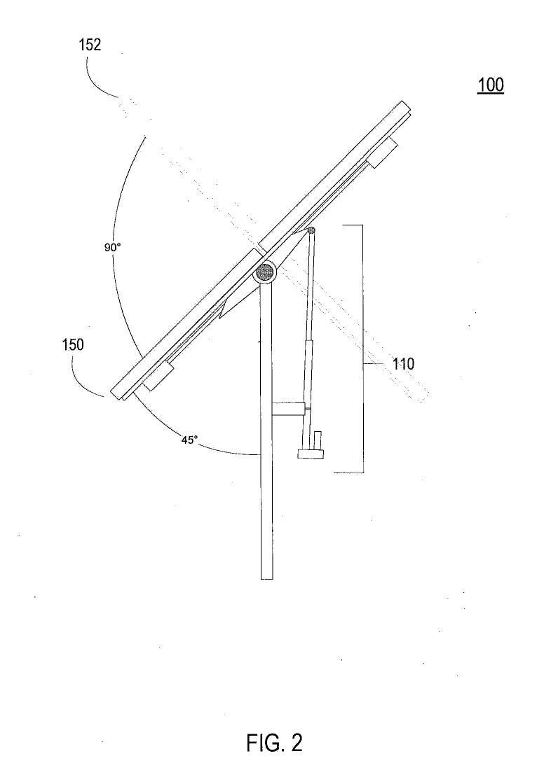

As illustrated in FIG. 2, the electromechanical tracker 110 is capable of rotating solar modules 115 through a 90 degree path from a first end position 150 to a second end position 152. In both end positions 150, 152, the solar modules 115 form a 45 degree angle with the post 130. Thus, in a horizontal position, the solar modules 115 would form a 90 degree angle with the post 130. It should be understood, of course, that the solar modules 115 may rotate through a path that is larger than or smaller than 90 degrees. Furthermore, the solar modules 115 may rotate through a path of 90 degrees but may form different angles with the post 130 at the end positions 150, 152. For example, at first end position 150 the solar modules 115 may form an angle of 40 degrees with the post 130 while at the second end position 152 the solar modules 115 form an angle of 50 degrees with the post 130. It should be further understood that the angle of the end positions 150, 152 with respect to the post 130 and the amount of rotation of'the solar modules 115 may vary according to the location of the solar tracking system 100 on the globe and the terrain on which the tracker is located. The solar tracking system 100 inclination rotation limits may be modified to allow for the solar module 115 to best track the path of the sun as it traverses the sky.

Referring again to FIG. 1A, the module support 112 is coupled to a lever arm 117, which is capable of rotating module support 112 about bearing and housing 116. The electromechanical tracker 110 comprises an AC or DC actuator motor 119 and screw arm 118 secured both to post 130 and lever arm 117.

The actuator motor 119 is controlled by a controller 111. The controller 111 generates tracking control signals that are sent to the actuator motor 119. The actuator motor 119 advances or retracts screw arm 118 in the direction and the amount indicated by the tracking control signals. In operation, lever arm 117 is actuated (adjusting the inclination angle of module support 112) as the actuator motor 119 advances or retracts screw arm 118. The controller 111 is thus able to position the module support 112 at any inclination angle along the module support's 112 path of rotation. In another embodiment, the lever arm 117 may be actuated using hydraulic or pneumatic means that is controlled by the controller 111.

The controller 111, which comprises at least a processor (PR) and memory (M), contains algorithms used to control the inclination angle of the module support 112 so that the solar module 115 tracks the path of the sun. For example, the controller 111 may contain an algorithm that positions the module support 112 at the first end position 150 at sunrise so that solar modules 115 are pointed at the sun. As the sun rises in the sky, the controller 111 periodically sends tracking control signals to the actuator motor 119, causing the screw arm 118 to adjust the inclination angle of the module support 112 so that the module support 112 and the solar modules 115 remain pointed at the sun as the sun moves across the sky during the day.

It is typically desired to have solar modules 115 pointed directly at the sun so that the sun is at an angle of incidence of substantially zero degrees with the solar module 115. This maximizes the ability of solar modules 115 to generate electrical power from the solar energy under optimum operating conditions (i.e., no clouds). If solar modules 115 are at an inclination angle such that an angle of incidence of the sun light is less than or greater than zero degrees, solar modules 115 may generate less power and in some cases operate less efficiently. Generally, after the sun sets, controller 111 sends a tracking control signal to actuator motor 119 to move the module support 112 back to a stow or generally horizontal position until the next morning.

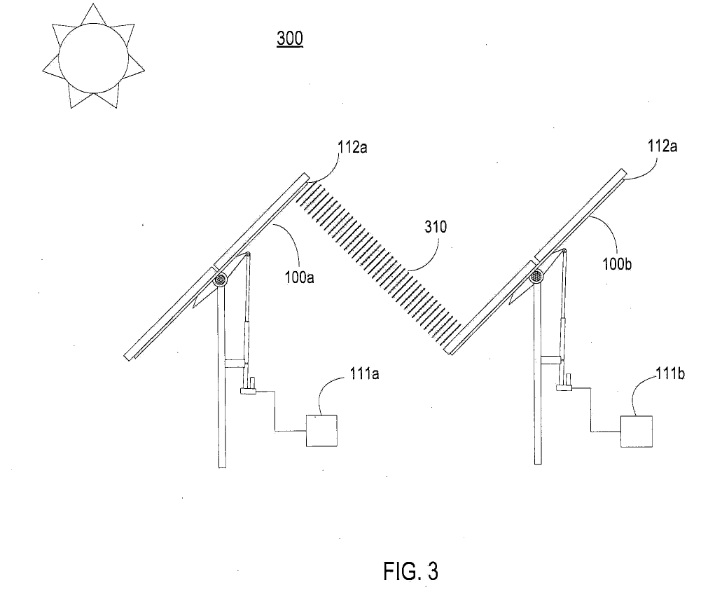

As illustrated in FIG. 3, a power generation system 300 may have a plurality of solar tracker systems 100a, 100b arranged in rows. The solar tracking systems 100a, 100b, may be arranged in close proximity to maximize the number of solar systems that are located in a given area. Each solar tracking system 100a, 100b has a respective controller 111a, 111b that controls the inclination angle of its corresponding solar tracking system 100a, 100b. In another embodiment, a single controller may control a plurality of solar tracking systems 100a, 100b.

When the sun is near the horizon, the module supports 112a, 112b of the solar tracking systems 100a, 100b approach or reside at the end positions 150, 152 (FIG. 2). At these inclination angles, the solar tracking systems 100a, 100b are able to maintain a substantially zero degree angle of incidence between their solar modules 115 and the direct irradiance of the sun. However, at these inclination angles, the solar tracking system 100a may cast a shadow 310 on the solar modules 115 of the solar tracking system 100b. In one embodiment, controllers 111a, 111b may operate to prevent the shadow 310 from solar tracking system 100a from being cast on one or more solar modules 115 of solar tracking system 100b. In these circumstances, the angle of incidence between the solar modules 115 of solar tracking systems 100a, 100b and the sun would not be zero degrees and would result in reduced efficiency of the solar modules 115 in solar tracking system 100a. However, all of the solar modules 115 in both solar tracking systems 100a, 100b would be absorbing direct irradiance and producing electric energy. In another embodiment, controllers 111a, 111b may operate to allow the shadow 310 to be cast on some of the solar modules 115 of solar tracking system 100b. As a result, all of the solar modules 115 may still have a zero degree angle of incidence with the sun, but the modules 115 in solar tracking system 100b that are partially shaded would not receive direct sunlight on their entire surface. However, because the subset of solar modules 115 that receive direct sun light may still have a zero degree angle of incidence with the sun, the solar tracking system 100b in some instances may actually produce more power than if the same solar modules where in direct sunlight but not at a zero degree angle of incidence.

As noted earlier, it is typically desired that the electromechanical tracker 110 will point the solar modules 115 directly at the sun so that the sun light has the optimal angle of incidence with the solar modules 115. However, under certain weather conditions, it may be desired to adjust the inclination angle of the solar modules 115 to a less-than-optimal angle of incidence. There are a number of situations where this would be useful.

For instance, during operation of the solar tracking system 100, soil, dust, and other residue, such as pollen, can collect on the solar modules 115. This residue reduces the efficiency of the solar modules 115 because it blocks sunlight. Removing the residue by hand or with a machine can be costly and time consuming in large power generation systems. To address this problem, the inclination angle of the solar modules 115 may be temporarily adjusted to allow precipitation to wash residue off the solar modules 115 thereby increasing the overall efficiency of the solar modules 115 when returned to tracking the path of the sun.

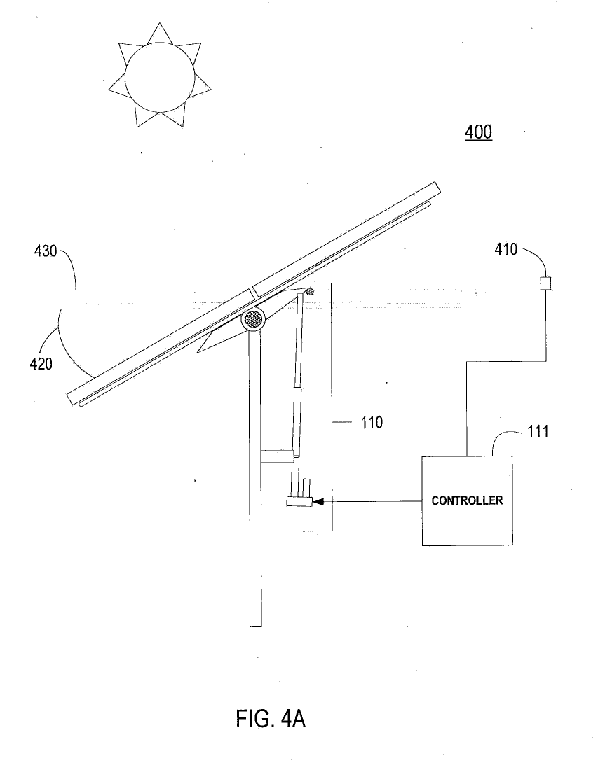

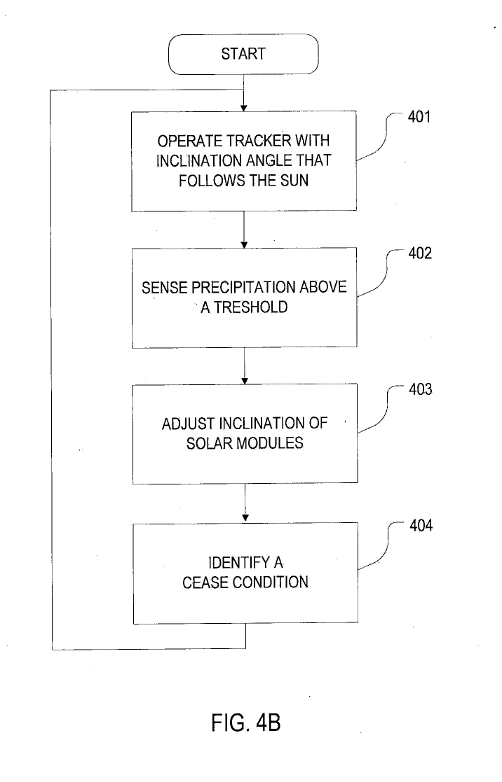

FIG. 4A illustrates a power generation system 400 that includes the solar tracking system 100 with the controller 111 coupled to a precipitation sensor 410. The precipitation sensor 410 is positioned to be exposed to precipitation.

FIG. 4B illustrates an exemplary control algorithm executed by the controller 111 to operate the electromechanical tracker 110 to adjust the inclination angle of the solar modules 115 based on a signal from the precipitation sensor 410. In a first step 401, the electromechanical tracker 110 is operated to cause the solar modules 115 to track a position of the sun. At step 402, once the sensor 410 senses precipitation above a threshold level, it sends a signal to the controller 111 indicating that it is precipitating. The controller 111 monitors the signals from the sensor 410 until the amount of precipitation rises above a threshold level needed to remove residue from the solar modules 115.

Once the threshold has been met, at step 403, the controller 111 sends a tracker control signal to the electromechanical tracker 110 to cause the electromechanical tracker 110 adjust the inclination angle of the solar modules 115 so that the solar modules 115 form a precipitation angle 420 that is more than 15 degrees offset from a horizontal position 430. At such an inclination angle, the precipitation on the solar modules 115 does not form puddles on the solar modules 115 that result in water spots, because the precipitation runs off the solar modules 115. Additionally, at these inclination angles the precipitation washes soil, dust, and other residue off the solar modules 115, cleaning the solar modules 115, thereby increasing efficiency. At step 404, the controller 111 identifies a cease condition and returns the solar modules 115 to an operation that sets an inclination angle that follows the sun. Such cease condition may include the precipitation sensed by the precipitation sensor 410 dropping below the precipitation threshold or an expiration of a set period, such as 30 minutes. The set period may vary based on the amount of precipitation sensed by the precipitation sensor 410. For example, the period may be shorter for heavier precipitation.

In one embodiment, the controller 111 may control the electromechanical tracker 110 to adjust the inclination angle of the solar modules 115 so that the solar modules 115 have the same inclination angle as a result of precipitation regardless of the starting inclination angle of the solar modules 115. For example, if the solar modules 115 have a starting inclination angle between the horizontal position 430 and the end position 152, the inclination angle may be adjusted so that the solar modules 115 have an inclination angle more than 15 degrees offset from the horizontal position 430 between the horizontal position 430 and the end position 150. Likewise, if the solar modules 115 have a starting inclination angle between the horizontal position 430 and the end position 150, the inclination angle may be adjusted to the same inclination angle. In another embodiment, the controller 111 determines how to adjust the inclination angle of the solar modules 115 based on the starting inclination angle of the solar modules 115. For example, if the solar modules 115 are more than 15 degrees offset from a horizontal position 430 when precipitation rises above a threshold level the controller 111 does not adjust the solar modules' 115 inclination angle but prevents the solar modules 115 from tracking the sun until one of the cease conditions discussed with respect to step 404 of FIG. 4 is fulfilled. As another example, the controller 111 minimizes the rotation of the solar modules 115 by rotating the solar modules 115 the fewest number of degrees to achieve a precipitation angle. For example, if the solar modules 115 have an inclination angle between the horizontal position 430 and the end position 152, the controller 111 adjusts the solar modules' 115 inclination angle to a precipitation angle 420 between the horizontal position 430 and the end position 152 so as to not move the solar modules 115 through the horizontal position 430. Reducing the amount of adjustment minimizes the movement of the solar modules 115, thereby reducing wear on the electromechanical tracker 110.

Another weather condition where it may be desired to adjust the inclination angle of the solar module 115 from tracking the sun is when the sky is overcast and clouds are blocking the direct irradiance of the sun. Under these conditions, only diffused irradiance is collected by the solar modules 115 in the solar tracking system 100. As a result, no advantage is achieved by tracking the sun's position because no direct irradiance can be collected.

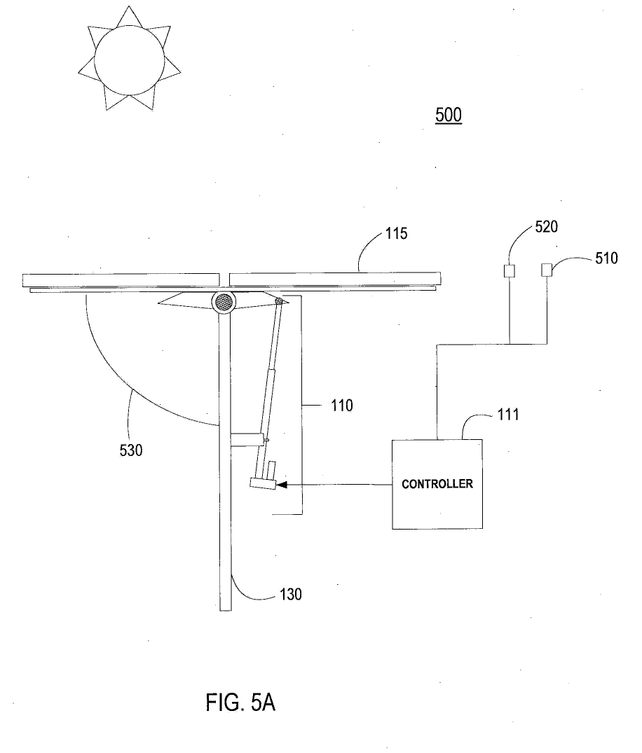

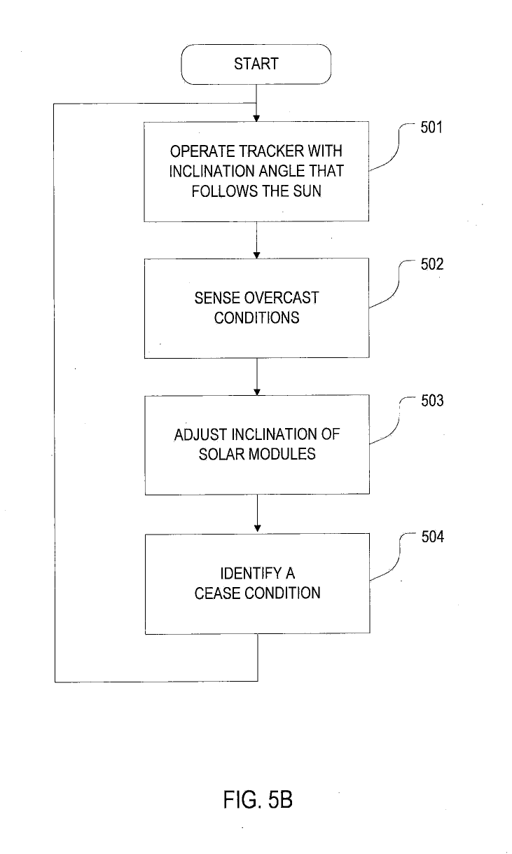

FIG. 5A illustrates a power generation system 500 that includes the solar tracking system 100 where the controller 111 adjusts the inclination angle of the solar modules 115 during overcast conditions. The controller 111 is coupled to a shadow band irradiance (SBI) sensor 510 and a global horizontal irradiance (GUI) sensor 520. The SBI sensor 510 senses only the amount of diffused irradiance reaching the earth's surface. The GHI sensor 520 senses the combined amount of direct and diffused irradiance reaching the earth's surface. When the output of the GHI sensor 520 equals the output of the SBI sensor 510 or approaches being equal by a preprogrammed set point, such as 90% or 95%, then it is overcast and only diffused irradiance is reaching the earth's surface at sensors' 510, 520 location. It should be understood, that the preprogrammed set point for determining overcast conditions may vary and may be determined to optimize the ability of the solar modules 115 to generate power.

FIG. 5B illustrates an exemplary control algorithm executed by the controller 111 to operate the electromechanical tracker 110 to adjust the inclination angle of the solar modules 115 based on the sensing of cloudy conditions, such as from signals from the SBI and GHI sensors 510, 520. In a first step 501, the electromechanical tracker 110 is operated to cause the solar modules 115 to track a position of the sun. At step 502, the controller 111 receives signals from the SBI and GHI sensors 510, 520. When the received signals from the SBI and GHI sensors 510, 520 indicate overcast conditions, that is when the signals are equal or approach being equal by a preprogrammed set point, at step 503 the controller 111 sends a tracker control signal to the electromechanical tracker 110 to adjust the inclination angle of the solar modules 115 so that the solar modules 115 are horizontal, i.e. forms an angle 530 that is substantially 90 degrees with respect to the post 130. At step 504, the solar modules 115 are maintained in the horizontal position until a cease condition is identified. A cease condition exists when the signals from the SBI and GHI sensors 510, 520 indicate that direct irradiance is now reaching the earth's surface, i.e. it is no longer overcast, or the sun has set.

Moving the solar modules 115 to a horizontal position and maintaining them there when it is overcast reduces wear on the electromechanical tracker 110 because electromechanical tracker 110 is not needlessly tracking the movement of the sun. It also reduces the need to power the electromechanical tracker 110 throughout the day; thereby decreasing parasitic power loses of the solar tracking system 100. Furthermore, the solar modules 115 may generate higher electrical output in a horizontal inclination when it is overcast than at other inclination angles.

Another weather condition where it may be desired to adjust the inclination angle of the solar module 115 is the presence of wind. Some loss of efficiency of the solar modules 115 may possibly occur when the solar modules 115 reach certain operating temperatures due to heating from the sun, ambient air temperature, or both. Wind may be used to cool the solar modules 115 in these situations. Thus, in such situations, an inclination angle that is not strictly optimal for sun tracking may be desired to exploit wind presence to decrease the operating temperature of solar modules 115.

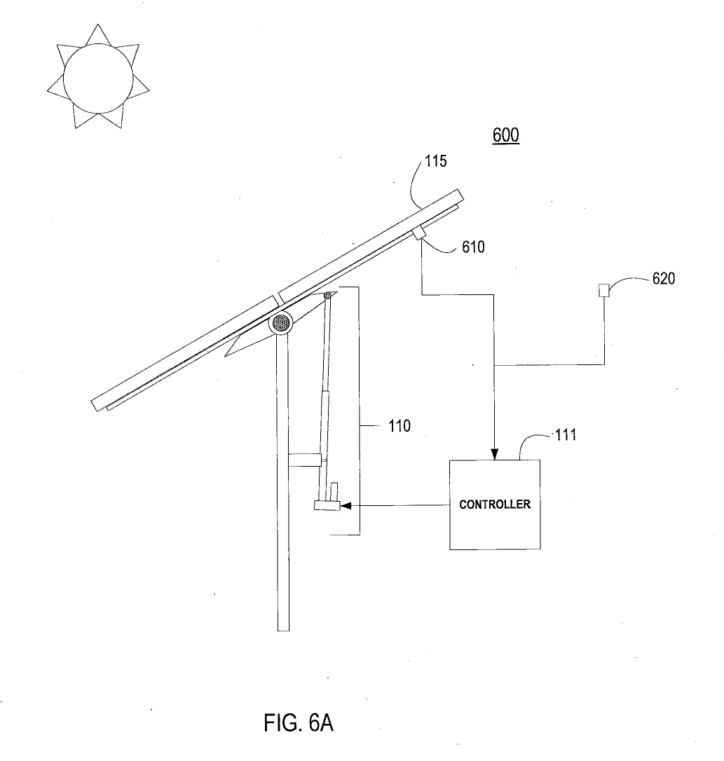

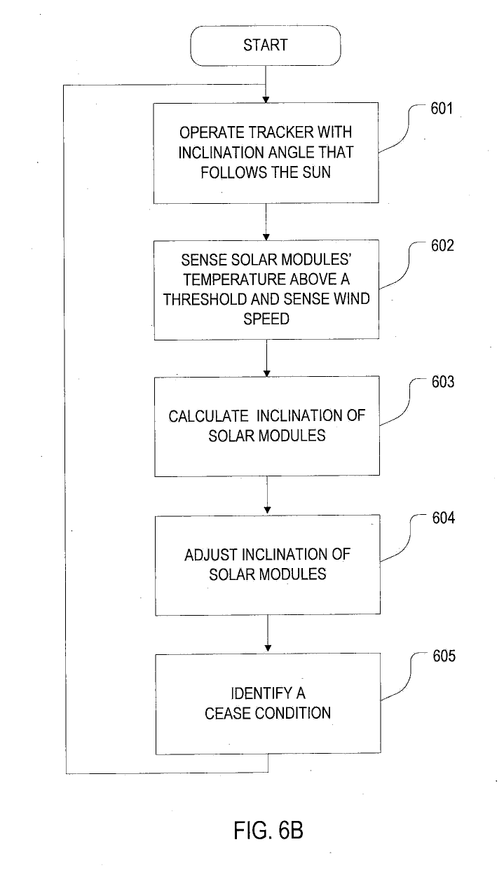

FIG. 6A illustrates a power generation system 600 that includes the solar tracking system 100 with the controller 111 that adjusts the inclination angle of the solar modules 115 when there is wind above a threshold level and the solar modules 115 are operating at a high temperature. The controller 111 is coupled to a solar module temperature sensor 610 and an air movement sensor 620. The solar module temperature sensor 610 senses the temperature of the solar modules 115. The air movement sensor 620 senses the direction and speed of air movement, e.g., wind.

FIG. 6B illustrates an exemplary control algorithm executed by the controller 111 to operate the electromechanical tracker 110 to adjust the inclination angle of the solar modules 115 based on signals from the temperature and air movement sensors 610, 620. In a first step 601, the electromechanical tracker 110 is operated to cause the solar modules 115 to track a position of the sun. At step 602, the controller 111 receives signals from the temperature and air movement sensors 610, 620. When the controller 111 determines that the temperature of the solar modules 115 are above an ideal operating temperature based on the signal received from the temperature sensor 610, and that wind is present, which is above a threshold level, it operates electromechanical tracker 110 to allow the wind to cool the solar modules 115. The cooling effect of wind on solar modules 115 is related to the surface area of the solar modules 115 that is in the path of the wind and the speed of the wind. A larger portion of the surface area of the solar modules 115 in the path of the wind leads to an increased cooling effect. Likewise, wind at higher speeds leads to an increased cooling effect. The controller 111 uses the direction and speed of the wind to calculate an inclination angle that positions a larger portion of the surface area of the solar modules 115 in the path of the wind to reduce the solar modules' 115 temperature at step 603. For example, with winds at lower speeds, but above the threshold level, the controller 111 may select a steeper inclination angle to position more surface area in the path of the wind than would be necessary with winds at higher speeds to achieve a desired cooling effect. It should be understood that the controller 111 may determine that the wind speed or direction are below threshold levels such that a change of inclination angle of the solar modules 115 will not significantly effect cooling and may not adjust the inclination angle of the solar modules 115 so that the solar modules 115 continue to track the sun.

Once a module inclination angle is determined, at step 604 the controller 111 sends a tracker control signal to the electromechanical tracker 110 to cause the electromechanical tracker 110 to adjust the inclination angle of the solar modules 115 to the determined inclination angle. At step 605, a cease condition is identified. A cease condition can be identified after the temperature of the solar modules 115 has been reduced a predetermined amount, at which time solar modules 115 may be returned to tracking the sun.

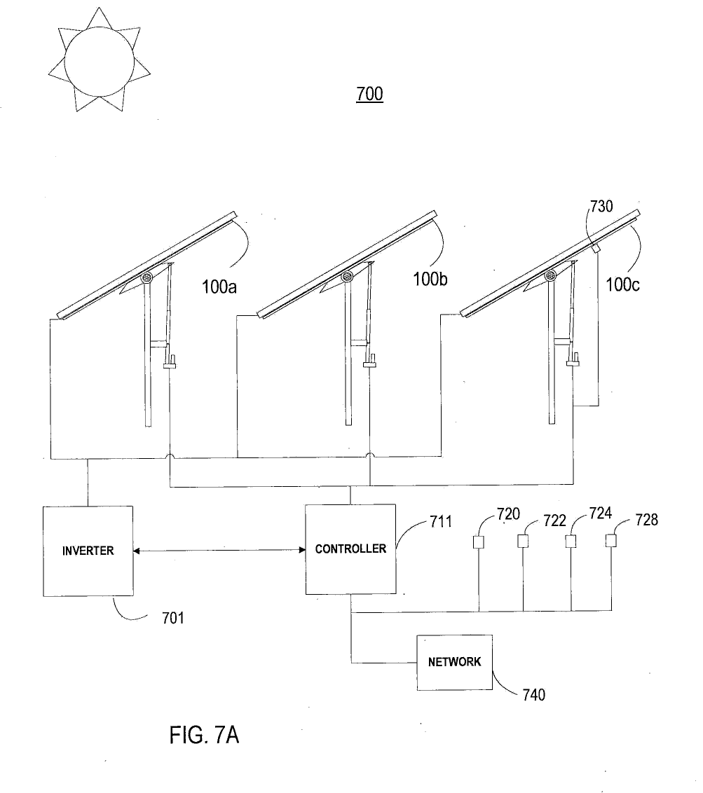

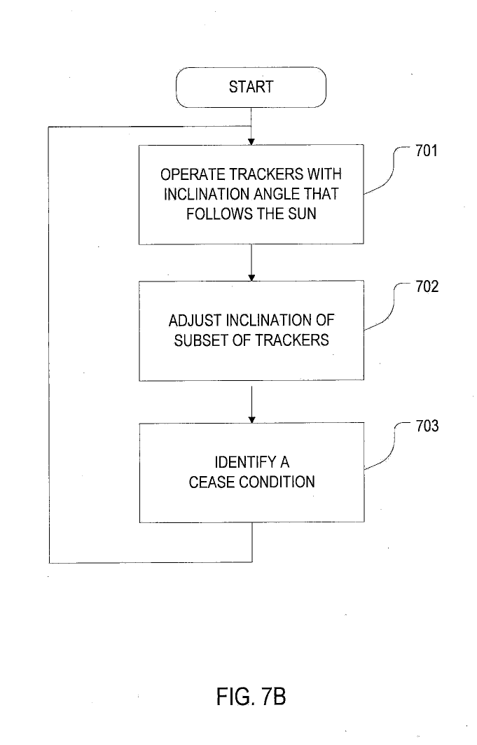

FIG. 7A shows a power generation system 700 that has a plurality of solar tracking systems 100a, 100b, 100c arranged in rows according to one embodiment. The solar tracking systems 100a, 100b, 100c may be arranged in close proximity to each other so as to maximize the number of solar tracking systems 100 that are located in a given area. Electromechanical trackers 110 on each solar tracker system 100a, 100b, 100c are connected to a common controller 711 that controls the inclination angle of associated module supports 112 and solar modules 115 mounted thereon. The common controller 711, as well as controllers, 111, 111a, 111b, identified above, may be implemented using a neural network. In another embodiment, each solar tracking system 100 may have its own controller 111 (as shown in FIGS. 1A-B) to control the actuator motor 119 and screw arm 118 on each solar tracking system 100, with common controller 711 providing operational commands to these controllers 111. The electrical outputs of each solar tracking system 100a, 100b, 100c are connected to an inverter 701, which can provide operating information, such as total DC voltage level or DC voltage level at each solar tracking system 100a, 100b, 100c to controller 711.

The controller 711 is also connected to a precipitation sensor 720, a GHI sensor 722, a SBI sensor 724, a air movement sensor 726, and a solar module temperature sensor 730. The controller 711 receives signals from the sensors 720, 722, 724, 726, 730 and may adjust the inclination angles of the solar tracking systems 100a, 100b, 100c according to the received signals as described above with respect to FIGS. 4, 5, and 6. The controller 711 may adjust the inclination angle of the solar tracking systems 100a, 100b, 100c individually according to inputs from the sensors 720, 722, 724, 726, 730. For example, in system 700, the solar tracking systems 100a, 100c on the edges of the system 700 may become more soiled and have reduced total DC voltage levels as compared to solar tracking system 100b in the middle of the system 700. When the precipitation sensor 720 senses precipitation above a precipitation threshold, the controller 711 may only adjust the inclination angles of the solar tracking systems 100a, 100c to allow the precipitation to clean their respective solar modules 115.

In another example, the solar tracking systems 100a, 100c on the edges of the system 700 may be more efficiently cooled by the wind than the solar tracking system 100b in the middle of the system 700 because wind speeds on the edges of the system 700 are typically higher than wind speeds in the middle of the system 700. As a result, when the air movement sensor 726 senses a wind that may be used to cool the solar modules 115 on solar tracking systems 100a, 100b, 100c and when the solar modules' 115 temperature is too high, the controller 711 may adjust the inclination angle of the solar tracking system 100b so that the solar tracking system 100b has a steeper inclination angle than the inclination angle of solar tracking systems 100a, 100c to compensate for the reduced wind speed and achieve similar cooling effects in all of the solar tracking systems 100a, 100b, 100c.

In yet another example, the controller 711 may operate to detect and characterize approaching cloud size, shape, opacity, speed, and trajectory based on the inputs from sensors 720, 722, 724, 726, 730 as well as meteorological data and other data collected from a network 740. The controller 711 may process this data to determine the effect of the weather on total DC voltage output levels of the solar tracking systems 100a, 100b, 100c as well as how to adjust the inclination angle of, for example, the solar modules 115 of the solar tracking systems 100a, 100b, 100c. Based on the information, the controller 711 may take preemptive action by ramping down the electrical output of the inverter 701 to compensate for the future reduction in power.

The controller 711 may also determine by using the sensors 720, 722, 724, 726, 730, information from network 740, or both that only a subset of the solar tracking systems 100a, 100b, 100c within the system 700 are receiving only diffused irradiance due to overcast conditions. For example, solar tracking system 100a may be subject to complete overcast conditions, while, solar tracking systems 100b, 100c are not. In this instance, the controller 711 may adjust the inclination angle of the solar tracking system 100a so that its solar modules 115 are in a horizontal position while allowing the solar tracking systems 100b, 100c to continue tracking the sun.

FIG. 7B illustrates an exemplary control algorithm executed by the controller 711 to adjust the inclination angle of the solar tracking systems 100a, 100b, 100c individually according to inputs from the sensors 720, 722, 724, 726, 730. In a first step 701, the controller 711 operates to cause the solar modules 115 of the solar tracking systems 100a, 100b, 100c to track a position of the sun. At step 702, based on the input from the sensors 720, 722, 724, 726, 730, in one embodiment, the controller 711 adjusts the inclination angle of a subset of the solar tracking systems 100a, 100b, 100c. For example, the controller 711 may adjust the inclination angle of solar tracking system 100a and not adjust the inclination angle of solar tracking systems 100b, 100c. In another example, the controller 711 may adjust solar tracking system 100a to a horizontal inclination angle to account cloud cover and adjust solar tracking system 100b to another inclination angle based on the temperature of the solar modules 115 in solar tracking system 100b and the presence of wind while not adjusting the inclination angle of solar tracking system 100c. At step 703, a cease condition is identified. A cease condition can be identified based on the input from the sensors 720, 722, 724, 726, 730, a predetermined period, or some other conditions, such as the cease conditions described with respect to FIGS. 4B, 5B, and 6B.

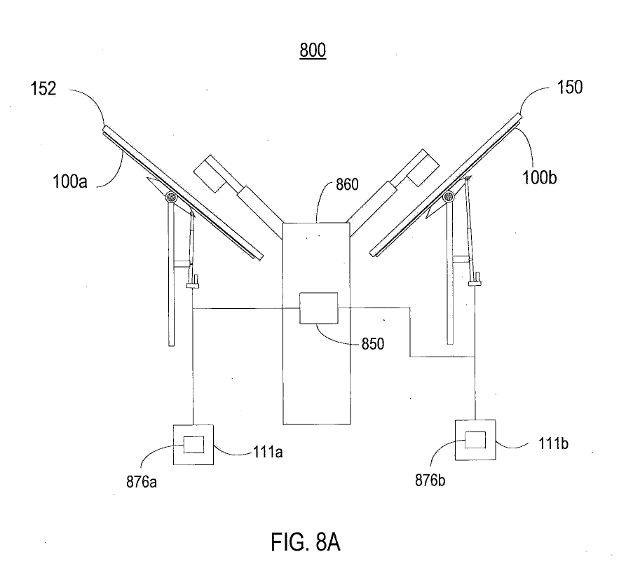

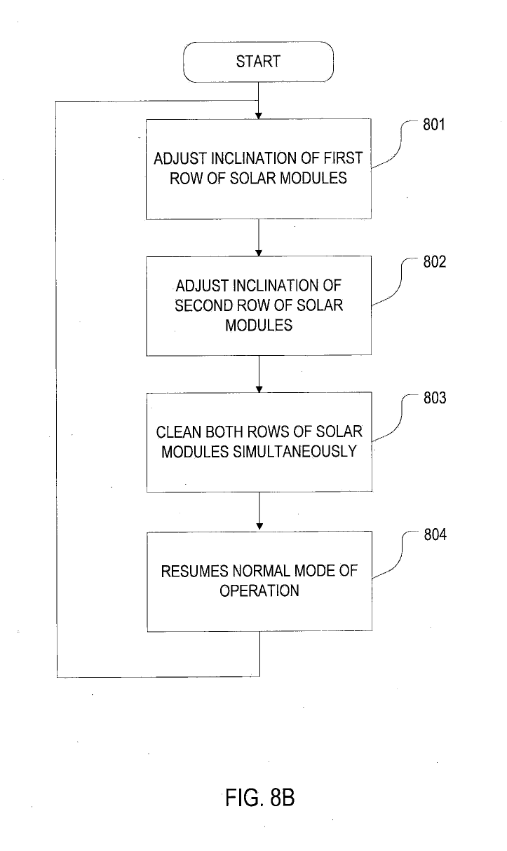

The ability to control the inclination angle of solar tracking systems individually may also be used to enable more efficient cleaning of solar tracking systems within a larger system. In known systems, a cleaning apparatus must go down every row within a system to clean the solar modules. FIG. 8A shows a power generation system 800 that has a plurality of solar tracking systems 100a, 100b arranged in rows according to one embodiment to allow the solar tracking systems 100a, 100b to be cleaned at the same time. During normal operation, the solar modules 115 of solar tracking systems 100a, 100b, point in the same direction while tracking the sun, as shown in FIGS. 3 and 7. When the solar modules 115 of solar tracking systems 100a, 100b are to be cleaned, the controllers 811a, 811b of the respective solar tracking systems 100a, 100b adjust the inclination angle of the solar tracking systems 100a, 100b, to allow both solar tracking systems 100a, 100b to face one direction, as shown in FIG. 8A and be cleaned at the same time.

FIG. 8B illustrates an exemplary control algorithm to adjust the inclination angle of the solar modules 115 of solar tracking systems 100a, 100b for cleaning. In a first step 801, he controller 811a sends a tracking control signal to the electromechanical tracker 110 of solar tracking system 100a to cause the electromechanical tracker 110 to place the solar modules 115 of solar tracking system 100a in the second end position 152. Next, at step 802, the controller 811b sends a tracking control signal to the electromechanical tracker 110 of solar tracking system 100b to cause the electromechanical tracker 110 to place the solar modules 115 of solar tracking system 100b in the first end position 150. In these positions, the solar modules 115 of solar tracking systems 100a, 100b may be cleaned simultaneously at step 803. At step 804, the solar modules of solar tracking systems 100a, 100b resume their normal mode of operations.

The controllers 811a, 811b, may send the tracking control signals to their respective electromechanical trackers 110 based on a set time schedule or a received signal. For example, the controllers 811a, 811b may position the solar tracking systems 100a, 100b for cleaning upon receiving a cleaning signal from a cleaning controller 850. Cleaning controller 850 may send the cleaning signal wirelessly to wireless controllers or antennas 876a, 876b of controllers 81 la, 811b. Cleaning controller 850 may also send the cleaning signal to the controllers 811a, 811b over a wired network. The solar tracking systems 100a, 100b may maintain their cleaning positions for a set period or until they receive an end cleaning signal from the cleaning controller 850. After a set period of time, or upon receiving an end cleaning signal, the controllers 811a, 811b send a tracking control signal to their respective electromechanical trackers 110 to cause the electromechanical trackers 110 to return the solar tracking systems 100a, 100b to their normal operating inclination angles.

This configuration allows, for example, a cleaning machine 860 with a cleaning controller 850 to emit a cleaning signal as the machine approaches the solar tracking systems 100a, 100b to cause the solar tracking systems 100a, 100b to assume the cleaning positions. The cleaning machine 860 may then move between the solar tracking systems 100a, 100b and clean their respective solar modules 115. Once the cleaning is complete, the cleaning controller 850 may emit an end cleaning signal to cause the solar tracking systems 100a, 100b to resume their normal mode of operations.

While several embodiments have been described in detail, it should be readily understood that the invention is not limited to the disclosed embodiments. Rather the embodiments can be modified to incorporate any number of variations, alterations, substitutions, or equivalent arrangements not heretofore described. Although certain features have been described with some embodiments, such features can be employed in other embodiments as well. While several embodiments have been described in detail, it should be readily understood that the invention is not limited to the disclosed embodiments. Rather the embodiments can be modified to incorporate any number of variations, alterations, substitutions, or equivalent arrangements not heretofore described. Accordingly, the invention is not limited by the foregoing description, but is only limited by the scope of the appended claims.

What is claimed as new and desired to be protected by Letters Patent of the United States is:

1. A photovoltaic power generation system comprising:
a solar module mounted on a rotatable module support;
a mechanism operable to adjust an inclination angle of the module support and the solar module; and
a controller to control the mechanism, the controller sending a signal to the mechanism to adjust the inclination angle of the solar module upon sensing at least one of the conditions within the group consisting of overcast conditions, temperature of the solar module rising above a threshold level, and precipitation above a threshold level.

2. The system of claim 1, wherein the controller causes the mechanism to adjust the inclination angle of the module support and solar module so as to track the position of the sun when the conditions are not sensed.

3. The system of claim 2, further comprising a precipitation sensor, wherein the controller controls the mechanism to adjust the inclination angle of the solar module when the precipitation sensor senses precipitation above the threshold level.

4. The system of claim 3, wherein the controller controls the mechanism to cause the inclination angle of the solar module to be offset by more than 15 degrees from a horizontal position.

5. The system of claim 4, wherein if the solar module is offset from the horizontal position in a first direction, the controller controls the mechanism to adjust the inclination angle of the solar module to be offset more than 15 degrees in the first direction.

6. The system of claim 4, wherein the controller controls the mechanism to cause the solar module to track a position of the sun a predetermined time after the solar module is inclined to be offset more than 15 degrees from a horizontal position.

7. The system of claim 6, wherein the predetermined time is determined according to the amount of precipitation sensed by the precipitation sensor.

8. The system of claim 1, further comprising a sensing system for sensing overcast conditions.

9. The system of claim 8, wherein the sensing system comprises a diffused irradiance sensor and a global irradiance sensor, wherein the controller uses data from the global irradiance sensor and data from the diffused irradiance sensor to determine if overcast conditions exits.

10. The system of claim 9, wherein overcast conditions exist when output of the global irradiance sensor approaches output of the diffused irradiance sensor by a preprogrammed set point.

11. The system of claim 8, wherein the controller controls the mechanism to adjust the inclination angle of the solar module to be horizontal if overcast conditions exits.

12. The system of claim 11, wherein the inclination angle of the solar module maintains horizontal position while it is overcast.

13. The system of claim 11, wherein the controller controls the mechanism to cause the solar module to track a position of the sun when it is not overcast.

14. The system of claim 1, further comprising an air movement sensor and a module temperature sensor, wherein the controller controls the mechanism to adjust the inclination angle of the solar module when the temperature of the solar module is above a temperature threshold and the air movement sensor senses air movement above an air movement threshold.

15. The system of claim 14, wherein the controller controls the mechanism to cause the solar module to track a position of the sun when the temperature of the solar module falls below the temperature threshold by a predetermined amount.

16. The system of claim 1, wherein the controller is implemented using a neural network.

17. A photovoltaic power generation system comprising:
a plurality of solar tracking systems, each system supporting a plurality of solar modules and including a respective mechanism to adjust an inclination angle of the supported solar modules;
at least one sensor for sensing weather conditions; and
a main controller to control the mechanisms of each solar tracking system independently, the main controller receiving data from the at least one sensor and controlling at least one of said mechanisms to adjust the modules associated with said at least one mechanism to a first inclination angle.

18. The system of claim 17, wherein the main controller is implemented using a neural network.

19. The system of claim 17, wherein the at least one sensor is an air movement sensor.

20. The system of claim 19, further comprising a temperature sensor, wherein the main controller adjusts the inclination angles of at least one of said mechanisms when the temperature sensor senses temperatures above a threshold and the air movement sensor senses air speed above a threshold.

21. The system of claim 20, wherein the main controller controls at least one other of the mechanisms to adjust the modules associated with the at least one other of the mechanisms to a second inclination angle different from said first inclination angle.

22. The system of claim 21, wherein the second inclination angle is steeper than the first inclination angle.

23. The system of claim 22, wherein the plurality of solar tracking systems are arranged in an array and the first subset of modules at the first inclination angle reside near the edge of the array.

24. The system of claim 17, wherein the sensor is a precipitation sensor and the main controller operates at least one of said mechanisms to adjust the inclination angles of modules associated with the at least one mechanism when the precipitation sensor senses precipitation above a set threshold.

25. The system of claim 24, wherein the main controller controls at least one of the mechanisms to cause the inclination angles of modules associated with the at least one of the mechanisms to be offset more than 15 degrees from a horizontal position.

26. The system of claim 17, further comprising a first sensor and a second sensor for sensing weather conditions, wherein the main controller controls a first of the mechanisms to adjust the inclination angle of modules associated with the first mechanism based on data from the first sensor and controls a second of the mechanisms to adjust the inclination angle of modules associated .with the second mechanism based on data from the second sensor.

27. A photovoltaic power generation system comprising:
a first tracking system for adjusting inclination angles a first plurality of solar modules;
a second tracking system for adjusting inclination angles of a second plurality of solar modules, the second tracking system positioned so that at one or more inclination angles the second plurality of modules, casts a shadow on the first plurality of solar modules; and
a controller to control the inclination angle of the second tracking system, wherein the controller directs the second tracking system to the one or more inclination angles that casts a shadow on the first plurality of solar modules.

28. The system of claim 27, wherein the controller directs the second tracking system to the one or more inclination angles so that irradiation from the sun has a substantially zero degree angle of incidence on the second plurality of solar modules.

29. A photovoltaic power generation system comprising:
a first set of solar modules on a first row of solar modules, the first set of solar modules having a first mechanism to adjust an inclination angle of the first set of solar modules;
a second set of solar modules on a second row of solar modules, the second set of solar modules a second mechanism to adjust an inclination angle of the second set of solar modules, the second row of solar module being parallel and adjacent to the first row of solar modules; and
a control system for controlling the first and second sets of solar modules, the control system controlling the first mechanism to adjust the inclination angle of the first row of solar modules and controlling the second mechanism to adjust the inclination angle of the second row of solar modules so that sun collecting sides of the first and second sets of solar modules face each other.

30. The system of claim 29, wherein the control system has a wireless receiver and the control system receives instructions for controlling the first and second mechanisms through the wireless receiver.

31. The system of claim 29, wherein the control system adjusts the inclination angles of the first and second sets of solar modules respectively after receiving a first wireless signal.

32. The system of claim 31, wherein the control system adjusts the inclination angles of the first and second sets of solar modules respectively to an inclination angle that permits cleaning.

33. The system of claim 31, wherein the control system adjusts the inclination angles of the first and second sets of solar modules respectively to track the sun after receiving a second wireless signal.

34. The system of claim 31, wherein the control system adjust the inclination angles of the first and second sets of solar modules respectively to track the sun after a set period of time.

35. A method for controlling solar modules in a photovoltaic power generation system, the method comprising the steps of:
producing data on weather conditions using a sensor system;
using a controller to determine an inclination angle for a solar module based on the produced data; and
setting the inclination angle of the solar module using a mechanism when at least one of the following conditions occur: clouds cover the sun, the temperature of the solar module rises above a threshold, and precipitation greater than a threshold value is falling on the solar module.

36. The method of claim 35, wherein the sensor system is a precipitation sensor and the produced data is the amount of precipitation sensed by the sensor, wherein the inclination angle determined by the controller is an angle offset more than 15 degrees from a horizontal position.

37. The method of claim 36, further comprising setting the inclination angle of the solar module so that the solar module tracks the position of the sun a predetermined time after the solar module is inclined to be offset more than 15 degrees from a horizontal position.

38. The system of claim 37, wherein the predetermined time is determined according to the amount of precipitation sensed by the precipitation sensor.

39. The method of claim 35, wherein said sensor system determines if overcast conditions exits, wherein the inclination angle determined by the controller is a horizontal position if overcast conditions exist.

40. The method of claim 39, wherein the inclination angle of the solar module maintains horizontal while it is overcast.

41. The system of claim 40, further comprising setting the inclination angle of the solar module so that the solar module tracks the position of the sun when it is not overcast.

42. The method of claim 35, wherein the sensor system comprises an air movement sensor and a sensor for measuring the temperature of the solar module, wherein the controller determines an inclination angle if the temperature of the solar module is above a temperature threshold.

43. The method of claim 42, further comprising setting the inclination angle of the solar module so that the solar module tracks the position of the sun when the temperature of the solar module falls below the temperature threshold by a predetermined amount.

44. A method for controlling solar tracking systems in a photovoltaic power generation system, the method comprising the steps of:
producing data on weather conditions using a sensor system having at least one sensor;
using a controller to independently determine an inclination angle for each of a plurality of solar tracking systems, each solar tracking system having one or more solar modules; and
setting the inclination angle of a first subset of solar tracking systems based on the received data.

45. The method of claim 44, wherein the sensor system comprises a temperature sensor and a air movement sensor, wherein setting the inclination angle of first subset of solar tracking systems occurs when the temperature sensor senses temperatures above a threshold and the air movement sensor senses air speed above a threshold.

46. The method of claim 45, further, comprising setting the inclination angle of a second subset of solar tracking systems based on the received data.

47. The method of claim 46, wherein the second subset of solar tracking systems has a steeper inclination angle than the first subset of solar tracking systems.

48. The method of claim 44, wherein the sensor system comprises a precipitation sensor and the step of setting the inclination angle of a solar tracking systems occurs when the precipitation sensor senses precipitation above a threshold.

49. The method of claim 48, wherein the inclination angle of the first subset of the tracker mechanisms is set to be more than 15 degrees from a horizontal position.

50. The method of claim 44, wherein the sensor system comprises a first and second sensor for sensing weather conditions.

51. The method of claim 50, further comprising setting the inclination angle of a second subset of solar tracking systems based on data from the second sensor, wherein the inclination angle of the first subset of solar tracking systems is set based on data from the first sensor.

52. A method for controlling solar modules in a photovoltaic power generation system, the method comprising the steps of:
adjusting an inclination angle of a first plurality of solar modules to track the sun;
adjusting an inclination angle of a second plurality of solar modules to track the sun, the second plurality of solar modules positioned so that at one or more inclination angles the second plurality of solar modules casts a shadow on the first plurality of solar modules.

53. A method of cleaning photovoltaic modules in a solar power generation system, the method comprising:
adjusting a first set of solar modules on a first row of solar modules from a sun collecting position to a first inclined position using a first mechanism controlled by a controller;
adjusting a second set of solar modules from the sun collecting position to a second inclined position using a second mechanism controlled by the controller, the second set of solar modules on a second row of solar modules that is parallel and adjacent to the first set of solar modules, wherein the first and second sets of solar modules face each other after being adjusted; and
cleaning the first and second set of solar modules.

54. The method of claim 53, further comprising returning the first and second sets of solar modules to the sun collecting position after the first and second sets of solar modules are cleaned.

55. The method of claim 53, further comprising receiving a first cleaning signal using the first and second controllers, wherein the steps of adjusting the first and second sets of solar modules occur after the step of receiving the first cleaning signal.

56. The method of claim 53, wherein the first cleaning signal is a wireless signal.

57. The method of claim 55, further comprising receiving a second cleaning signal using the first and second controllers, wherein the step of returning the first and second sets of solar modules occurs after the step of receiving the second cleaning signal.

58. The method of claim 53, wherein in the sun collecting position, the first and second set of solar modules track the position of the sun.
